(19) United States
(12) Patent Application Publication
(10) Pub. No.: US 2014/0332256 A1
(43) Pub. Date: Nov. 13, 2014

(54) MICRO-WIRE ELECTRODE STRUCTURE HAVING NON-LINEAR GAPS

(71) Applicants: RONALD STEVEN COK, Rochester, NY (US); John Andrew Lebens, Rush, NY (US)

(72) Inventors: RONALD STEVEN COK, Rochester, NY (US); John Andrew Lebens, Rush, NY (US)

(21) Appl. No.: 13/891,434

(22) Filed: May 10, 2013

(51) Int. Cl. H05K 1/02

(52) U.S. Cl. CPC H05K 1/0274; H05K 2201/0302; H05K 2201/09245
USPC 174/253

(57) ABSTRACT

A micro-wire electrode structure having non-linear gaps includes a substrate and a plurality of intersecting micro-wires formed over, on, or in the substrate. The plurality of intersecting micro-wires includes first micro-wires extending in a first direction and second micro-wires extending in a second direction different from the first direction. The second micro-wires intersect the first micro-wires. The plurality of intersecting micro-wires forms an array of electrically isolated electrodes, each electrode including both first and second micro-wires. Each electrode is separated from an adjacent electrode in the array of electrodes by micro-wire gaps in at least some of the micro-wires, the micro-wire gaps located in a non-linear arrangement.

### FIELD OF THE INVENTION

The present invention relates to apparently transparent micro-wire electrodes.

### BACKGROUND OF THE INVENTION

Transparent conductors are widely used in the flat-panel display industry to form electrodes that are used to electrically switch the light-emitting or light-transmitting properties of a display pixel, for example, in liquid crystal or organic light-emitting diode displays. Transparent conductive electrodes are also used in touch screens in conjunction with displays. In such applications, electrodes are typically arranged in two orthogonal arrays of substantially linear electrodes providing two-dimensional matrix control or sensing. The transparency, invisibility, and conductivity of the electrodes are important attributes. In general, it is desired that transparent conductors have a high transparency (for example, greater than 90% in the visible spectrum) and a high electrical conductivity (for example, less than 10 ohms/square).

Touch screens with apparently transparent electrodes are widely used with electronic displays, especially for mobile electronic devices. Touch screens mounted over a display device are largely transparent so a user can view displayed information through the touch-screen and readily locate a point on the touch-screen to touch and thereby indicate the information relevant to the touch. By physically touching, or nearly touching, the touch screen in a location associated with particular information, a user can indicate an interest, selection, or desired manipulation of the associated particular information. The touch screen detects the touch and then electronically interacts with a processor to indicate the touch and touch location. The processor can then associate the touch and touch location with displayed information to execute a programmed task associated with the information. For example, graphic elements in a computer-driven graphic user interface are selected or manipulated with a touch screen mounted on a display that displays the graphic user interface.

Touch screens use a variety of technologies, including resistive, inductive, capacitive, acoustic, piezoelectric, and optical technologies. Such technologies and their application in combination with displays to provide interactive control of a processor and software program are well known in the art. Capacitive touch-screens are of at least two different types: self-capacitive and mutual-capacitive. Self-capacitive touch-screens employ an array of transparent electrodes each of which, in combination with a touching device (e.g. a finger or conductive stylus), forms a temporary capacitor whose capacitance is detected. Mutual-capacitive touch-screens can employ an array of transparent electrode pairs that form capacitors whose capacitance is affected by a conductive touching device. In either case, each capacitor in the array is tested to detect a touch and the physical location of the touch-detecting electrode in the touch-screen corresponds to the location of the touch. For example, U.S. Pat. No. 7,663,607 discloses a multipoint touch-screen having a transparent capacitive sensing medium configured to detect multiple touches or near touches that occur at the same time and at distinct locations in the plane of the touch panel and to produce distinct signals representative of the location of the touches on the plane of the touch panel for each of the multiple touches. The disclosure teaches both self- and mutual-capacitive touch-screens.

Since touch-screens are largely transparent, any electrically conductive materials located in the transparent portion of the touch-screen either employ transparent conductive materials or employ conductive elements that are too small to be readily resolved by the eye of a touch-screen user. Transparent conductive metal oxides are well known in the display and touch-screen industries and have a number of disadvantages, including limited transparency and conductivity and a tendency to crack under mechanical or environmental stress. Typical prior-art conductive electrode materials include conductive metal oxides such as indium tin oxide (ITO) or very thin layers of metal, for example silver or aluminum or metal alloys including silver or aluminum. These materials are coated, for example, by sputtering or vapor deposition, and are patterned on display or touch-screen substrates, such as glass. However, the current-carrying capacity of such electrodes is limited, thereby limiting the amount of power that can be supplied to the pixel elements. Moreover, the substrate materials are limited by the electrode material deposition process (e.g. sputtering). Thicker layers of metal oxides or metals increase conductivity but reduce the transparency of the electrodes.

Various methods of improving the conductivity of transparent conductors are taught in the prior art. For example, U.S. Pat. No. 6,812,637 describes an auxiliary electrode to improve the conductivity of the transparent electrode and enhance the current distribution. Such auxiliary electrodes are typically provided in areas that do not block light emission, e.g., as part of a black-matrix structure, but are useful only in displays having a reduced fill factor.

It is also known in the prior art to form conductive traces using nano-particles including, for example silver. The synthesis of such metallic nano-crystals is known. For example, U.S. Pat. No. 6,645,444 describes a process for forming metal nano-crystals optionally doped or alloyed with other metals. U.S. Patent Application Publication No. 2006/0057502 entitled “Method of forming a conductive wiring pattern by laser irradiation and a conductive wiring pattern” describes fine wirings made by drying a coated metal dispersion colloid into a metal-suspension film on a substrate, pattern-wise irradiating the metal-suspension film with a laser beam to aggregate metal nano-particles into larger conductive grains, removing non-irradiated metal nano-particles, and forming metallic wiring patterns from the conductive grains. However, such wires are not transparent and thus the number and size of the wires limits the substrate transparency as the overall conductivity of the wires increases.

Touch-screens including very fine patterns of conductive elements, such as metal wires or conductive traces are known. For example, U.S. Patent Application Publication No. 2011/0007011 teaches a capacitive touch screen with a mesh electrode, as does U.S. Patent Application Publication No. 2010/0026664.

It is known that micro-wire electrodes in a touch-screen can optically interact with pixels in a display and various layout designs are proposed to avoid such interaction. Thus, the pattern of micro-wires in a transparent electrode is important for optical as well as electrical reasons.

In designs using arrays of substantially linear micro-wire electrodes, adjacent electrodes are electrically isolated, typically by physically separating micro-wires in one electrode from micro-wires in another electrode. These separations can form patterns that are visible. For example, referring to the prior-art illustration of FIG. 14, micro-wires 50 formed on substrate 30 form electrically isolated first and second electrodes 70, 80 separated by micro-wire gaps 40. U.S. Patent Application Publication No. 2012/0031746 and U.S. Patent Application Publication No. 2011/0291966 illustrate micro-wires arranged in a diamond pattern forming electrodes separated by gaps between the electrodes.

In other arrangements, referring to U.S. Pat. No. 8,179,381, dummy wires electrically isolated from, and located between, electrodes are separated by gaps between the dummy wires and the electrodes. For example, referring to the prior-art illustration of FIG. 15, micro-wires 50 formed on substrate 30 form first and second electrodes 70, 80. Dummy micro-wires 60 form electrically isolated dummy electrode 90. First and second electrodes 70, 80, and dummy electrode 90 are electrically isolated by micro-wire gaps 40. In these arrangements, the micro-wire gaps 40 can be visible to observers.

Mutual-capacitive touch screens typically include arrays of capacitors whose capacitance is repeatedly tested to detect a touch. In order to detect touches rapidly, highly conductive electrodes are useful. In order to readily view displayed information on a display at a display location through a touch screen, it is useful to have a highly transparent and apparently invisible touch screen. There is a need, therefore, for an improved method and device for providing micro-wire electrodes with increased conductivity and transparency and reduced visibility.

### SUMMARY OF THE INVENTION

In accordance with the present invention, a micro-wire electrode structure having non-linear gaps comprises:

a substrate;

a plurality of intersecting micro-wires formed over, on, or in the substrate, the plurality of intersecting micro-wires including first micro-wires extending in a first direction and second micro-wires extending in a second direction different from the first direction, the second micro-wires intersecting the first micro-wires;

wherein the plurality of intersecting micro-wires forms an array of electrically isolated electrodes, each electrode including both first and second micro-wires; and

wherein each electrode is separated from an adjacent electrode in the array of electrodes by micro-wire gaps in at least some of the micro-wires, the micro-wire gaps located in a non-linear arrangement.

The present invention provides an apparently transparent and invisible micro-wire electrode with improved conductivity and transparency and reduced visibility. The apparently transparent electrode can be used in a variety of electronic devices such as touch screens and integrated with other electronic devices such as displays. The apparently transparent electrode of the present invention is particularly useful in capacitive touch-screen devices.

### BRIEF DESCRIPTION OF THE DRAWINGS

The above and other features and advantages of the present invention will become more apparent when taken in conjunction with the following description and drawings wherein identical reference numerals have been used to designate identical features that are common to the figures, and wherein:

FIG. 1 is a plan view of micro-wire electrodes illustrating an embodiment of the present invention;

FIG. 2 is a plan view of micro-wire electrodes illustrating another embodiment of the present invention;

FIG. 3 is a plan view of curved micro-wires in micro-wire electrodes according to an embodiment of the present invention;

FIG. 4 is a plan view of micro-wire electrodes illustrating yet another embodiment of the present invention;

FIG. 5 is a plan view of micro-wire electrodes illustrating an alternative embodiment of the present invention;

FIG. 6 is a plan view of micro-wire electrodes illustrating an embodiment of the present invention;

FIG. 7 is a plan view of micro-wire electrodes with a dummy electrode illustrating another embodiment of the present invention;

FIG. 8 is a plan view of micro-wire electrodes illustrating another embodiment of the present invention;

FIG. 9 is a plan view of micro-wire electrodes with display sub-pixels illustrating an embodiment of the present invention;

FIG. 10 is a cross section of micro-wire electrodes illustrating an embodiment of the present invention;

FIG. 11 is a plan view of micro-wire electrodes with display sub-pixels illustrating an alternative embodiment of the present invention;

FIG. 12 is a plan view of two layers of orthogonal micro-wire electrodes illustrating an embodiment of the present invention;

FIG. 13 is a cross section of two layers of micro-wire electrodes illustrating an embodiment of the present invention;

FIG. 14 is a plan view of micro-wire electrodes according to the prior art;

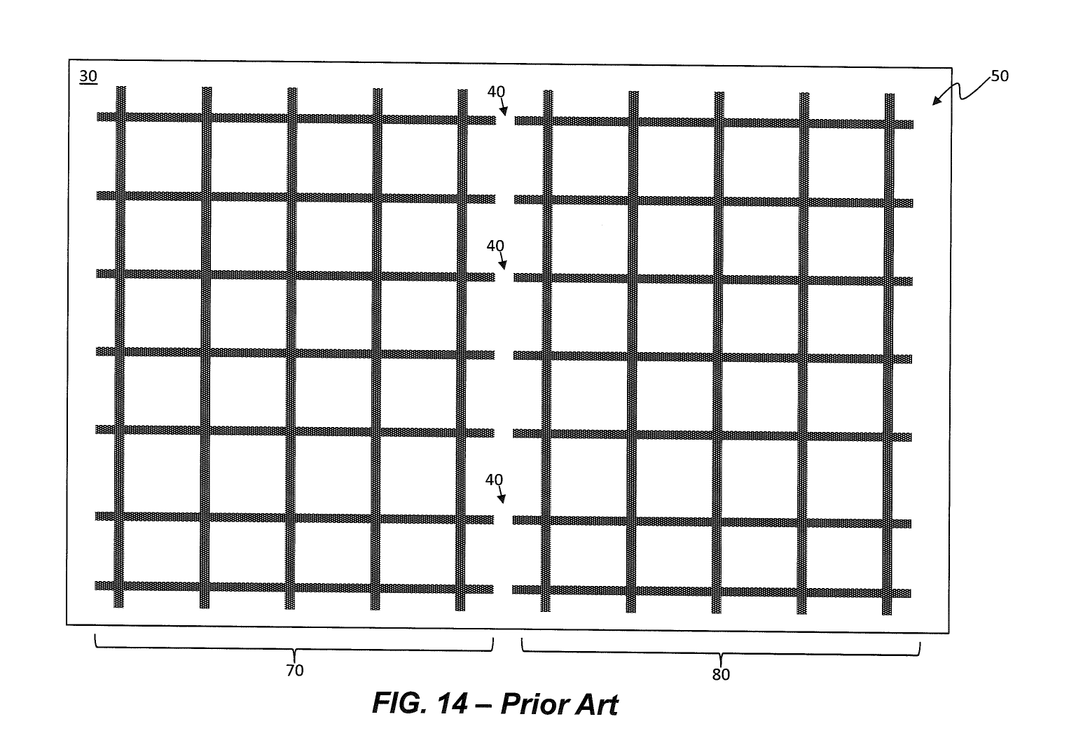

FIG. 15 is a plan view of micro-wire electrodes with a dummy electrode according to the prior art; and

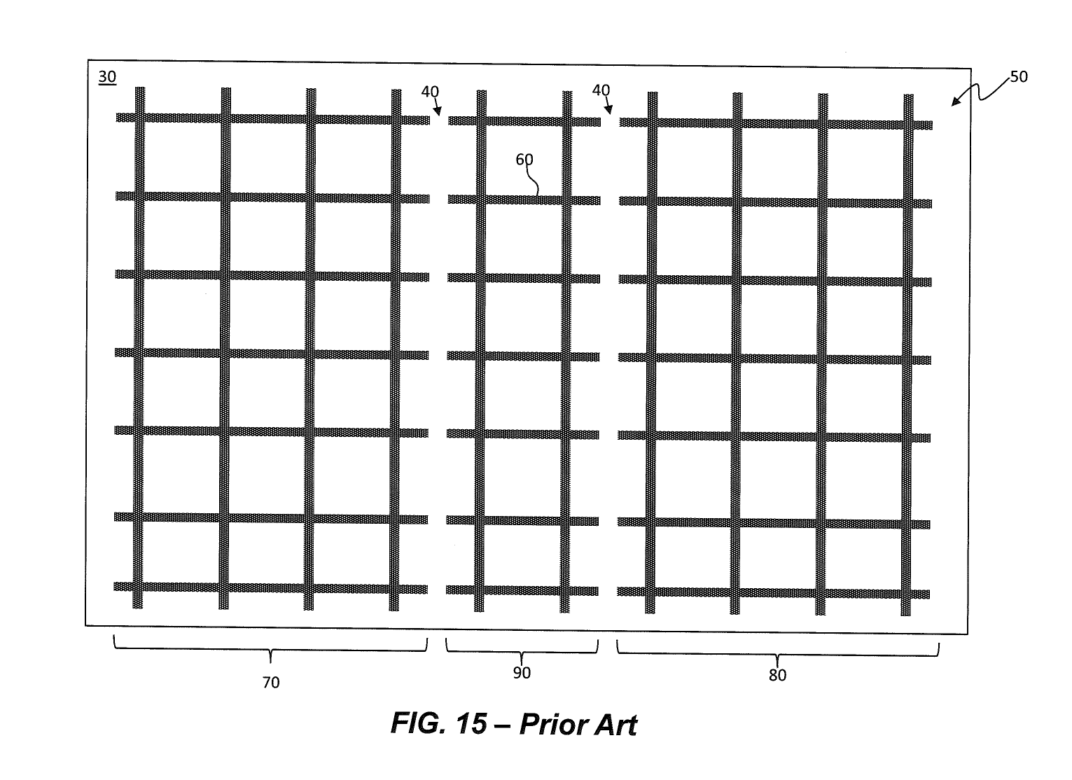

FIG. 16 is a plan view of micro-wire electrodes surrounding dummy micro-wires according to an embodiment of the present invention.

The drawings are not to scale, since the various dimensions vary too greatly to permit depiction to scale.

### DETAILED DESCRIPTION OF THE INVENTION

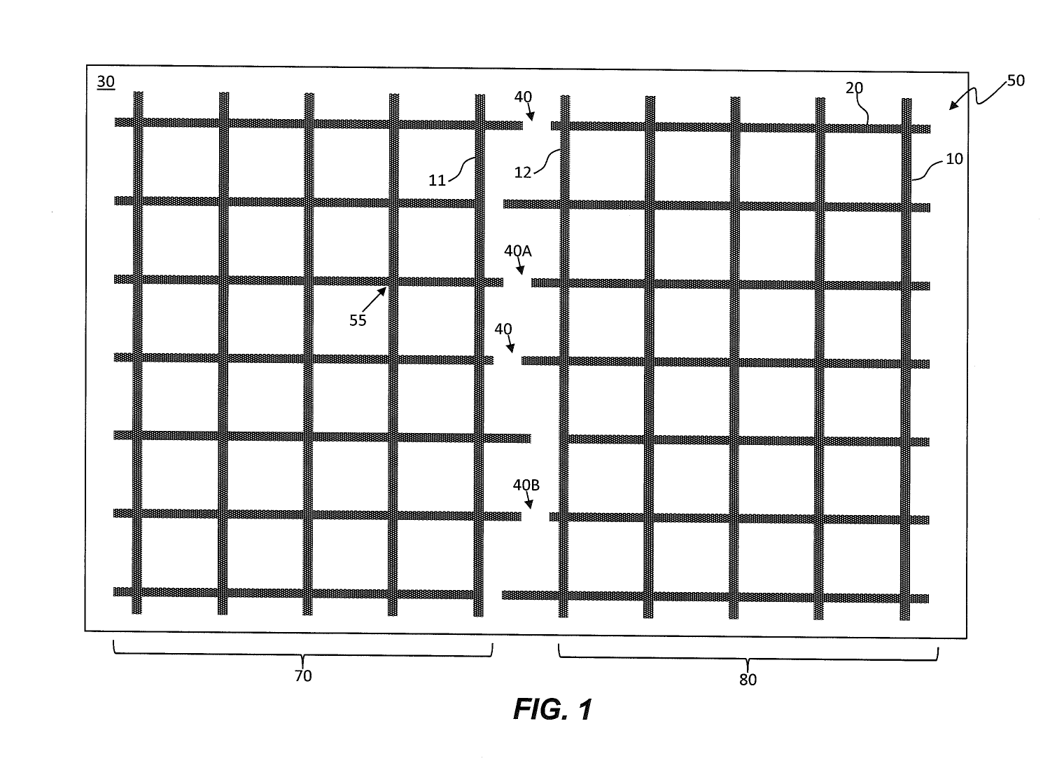

Referring to FIG. 1, an embodiment of the present invention includes a substrate 30 and a plurality of intersecting micro-wires 50 formed over, on, or in substrate 30. The plurality of intersecting micro-wires 50 include first micro-wires 10 extending in a first direction and second micro-wires 20 extending in a second direction different from the first direction. The second micro-wires 20 intersect the first micro-wires 10 at intersecting locations 55. The plurality of intersecting micro-wires 50 forms an array of electrically isolated first and second electrodes 70, 80, each first and second electrode 70, 80 including both first and second micro-wires 10, 20. Each first electrode 70 is separated from an adjacent second electrode 80 in the array of first and second electrodes 70, 80 by micro-wire gaps 40 in at least some of micro-wires 50. Micro-wire gaps 40 are located in a non-linear arrangement and electrically isolate adjacent first and second electrodes 70, 80. First and second electrodes 70, 80 are adjacent when there is no other electrode located between them.

As used herein, a non-linear arrangement of micro-wire gaps 40 is an arrangement in which a single straight line cannot intersect the center of micro-wire gaps 40 between adjacent first and second electrodes 70, 80. In another embodiment of the present invention, a single line cannot intersect any portion of micro-wire gaps 40 between adjacent first and second electrodes 70, 80. Both of these non-linear arrangements are shown in FIG. 1. In an embodiment, micro-wire gaps 40 have an irregular or random arrangement.

In an embodiment, micro-wires 50 form an interconnected electrically conductive mesh. Preferably, micro-wires 50 are sufficiently thin and spatially separated that they are not readily visible to the human visual system. However, micro-wire gaps 40 forming separations or interruptions of micro-wires 50 can be visible and draw attention from the human visual system. By locating micro-wire gaps 40 in a non-linear arrangement, micro-wire gaps 40 and associated micro-wires 50 are less visible, thereby rendering the micro-wire electrode structure invisible and apparently transparent.

First and second micro-wires 10, 20 are arbitrary designations of groups of micro-wires 50 and the designations can be interchanged. A micro-wire 50 with a micro-wire gap 40 is considered herein to be a single micro-wire 50 having separate portions. Separate portions of a single micro-wire 50 can be electrically isolated and can be parts of different micro-wire first and second electrodes 70, 80.

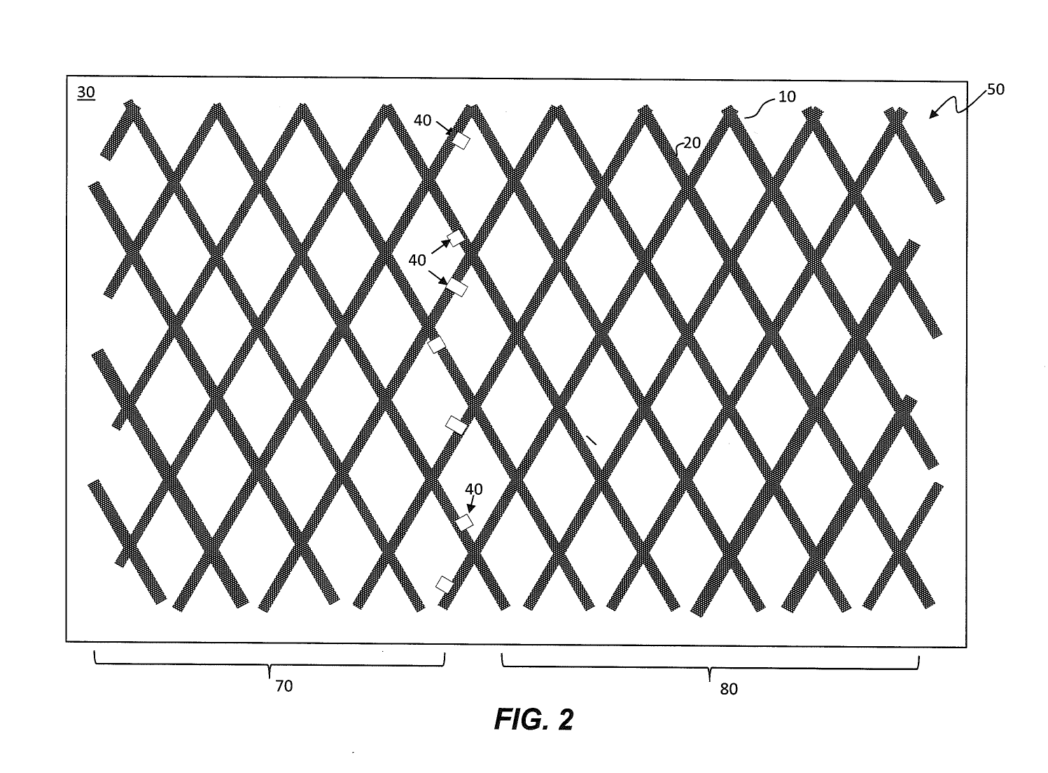

First and second micro-wires 10, 20 can extend at any different angles. As shown in FIG. 1, first micro-wires 10 extend in a direction orthogonal to the direction in which second micro-wires 20 extend. Referring to FIG. 2, micro-wires 50 formed on, in, or above substrate 30 include first micro-wires 10 and second micro-wires 20. First micro-wires 10 extend in a direction 60 degrees different from the direction in which second micro-wires 20 extend. Micro-wire gaps 40 are located in a non-linear arrangement and electrically isolate adjacent first and second electrodes 70, 80.

In an embodiment, and as illustrated in FIGS. 1 and 2, micro-wires 50 are arranged in a single, consistent pattern over substrate 30. The consistent pattern is interrupted by micro-wire gaps 40. In another embodiment, different first and second electrodes 70, 80 have different patterns or arrangements of micro-wires 50, but are still separated by micro-wire gaps 40 in a non-linear arrangement (not shown). The non-linear arrangement of micro-wire gaps 40 is independent of the arrangement of micro-wires 50 or any micro-wire pattern.

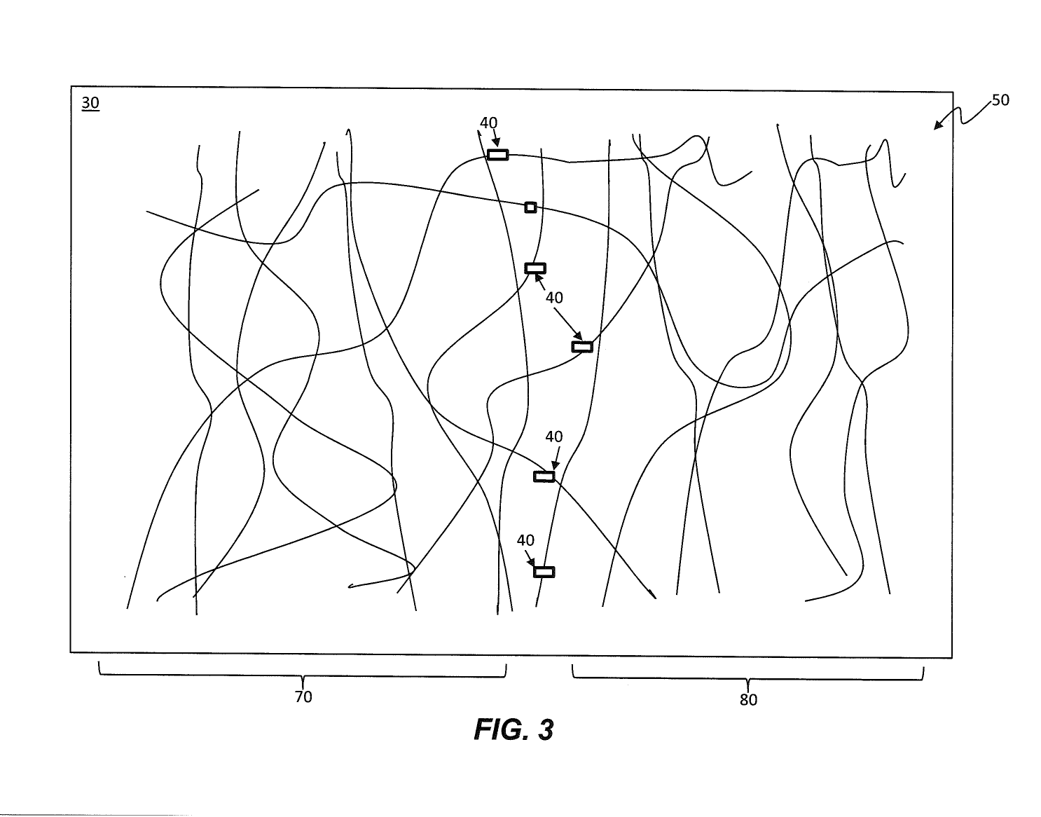

In the embodiments of FIGS. 1 and 2, first micro-wires 10 are straight and parallel to each other. Similarly, second micro-wires 20 are straight and parallel to each other. First micro-wires 10 and second micro-wires 20 extend at different angles over, on, or in substrate 30 to form intersections. In alternative embodiments, first or second micro-wires 10, 20 are not parallel or straight and first micro-wires 10 are not distinguishable as a group from second micro-wires 20. For example, as illustrated in FIG. 3, micro-wires 50 can be curved, can have curved portions, or are randomly arranged so that there is no perceptible micro-wire pattern with distinguishable groups of intersecting micro-wires 50. In such an embodiment, a micro-wire electrode structure includes substrate 30. A plurality of intersecting micro-wires 50 formed over, on, or in substrate 30 forms an array of adjacent electrically isolated first and second electrodes 70, 80 separated by micro-wire gaps 40 in at least some of micro-wires 50. Micro-wire gaps 40 are located in a non-linear arrangement. At least some micro-wires 50 are curved or have curved portions.

In alternative embodiments of the present invention, micro-wires 50 can include additional intersecting micro-wires 50 for example straight micro-wires 50 extending in a direction different from the directions of first micro-wires 10 or second micro-wires 20 (not shown).

In some embodiments in which micro-wires 50 are divisible into distinguishable groups of first and second micro-wires 10, 20, micro-wire gaps 40 are formed in only first micro-wires 10 (not shown) or micro-wire gaps 40 are formed only in second micro-wires 20 (as shown in FIG. 1). Referring to FIG. 2, micro-wires 50 on, in or above substrate 30 include first and second micro-wires 10, 20 that form first and second electrodes 70, 80 separated by micro-wire gaps 40 formed in both first micro-wires 10 and in second micro-wires 20.

Furthermore, in various embodiments, the number of micro-wire gaps in either first micro-wires 10 or second micro-wires 20 is controlled. In the embodiment of FIG. 1, a first micro-wire gap 40A is formed in a second micro-wire 20 located between two first micro-wires 11, 12. A second micro-wire gap 40B is formed in a different second micro-wire 20 located between the same two first micro-wires 11, 12. No first micro-wires 10 include a micro-wire gap 40.

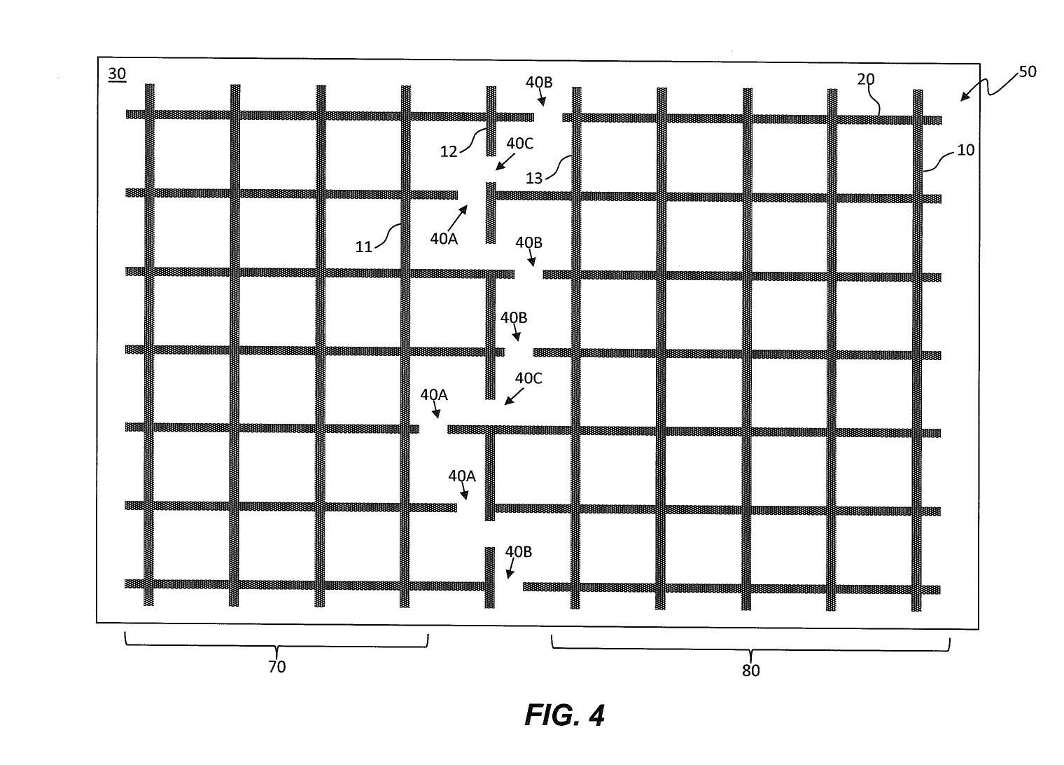

Referring to FIG. 4 in an alternative embodiment, micro-wires 50 are formed in, on, or above substrate 30 including first and second micro-wires 10, 20. A first micro-wire gap 40A is formed in a second micro-wire 20 located between two first micro-wires 11, 12. A second micro-wire gap 40B is formed in a different second micro-wire 20 located between two different first micro-wires 12, 13. As shown in FIG. 4, first micro-wires 11, 12 and two different first micro-wires 12, 13 have one first micro-wire 10 in common (first micro-wire 12). Thus, only first micro-wire 12 includes a micro-wire gap 40C. Such arrangements can further reduce visibility of first and second micro-wire gaps 40A, 40B, and micro-wire gap 40C.

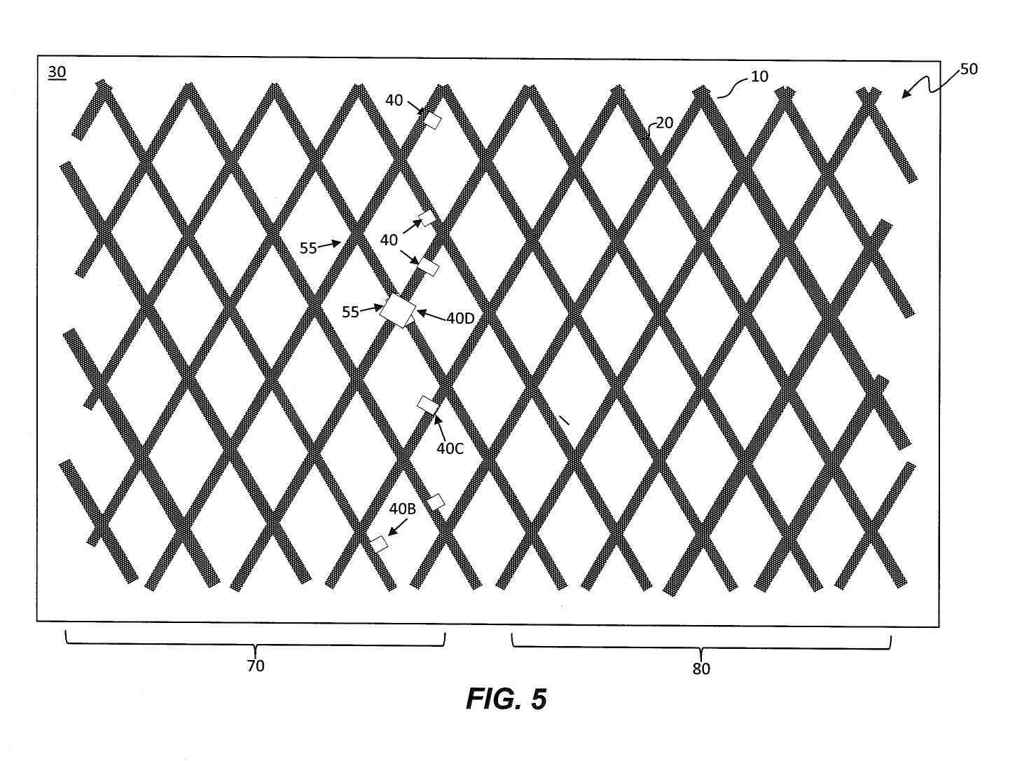

In yet another embodiment of the present invention, referring to FIG. 5, the plurality of intersecting micro-wires 50 on, in or above substrate 30 form intersections at intersecting locations 55. Micro-wires 50 include first and second micro-wires 10, 20 that form first and second electrodes 70, 80 separated by micro-wire gaps 40C formed in first micro-wires 10, second micro-wire gaps 40B formed in second micro-wires 20, and at least one micro-wire gap 40D formed in an intersecting location 55.

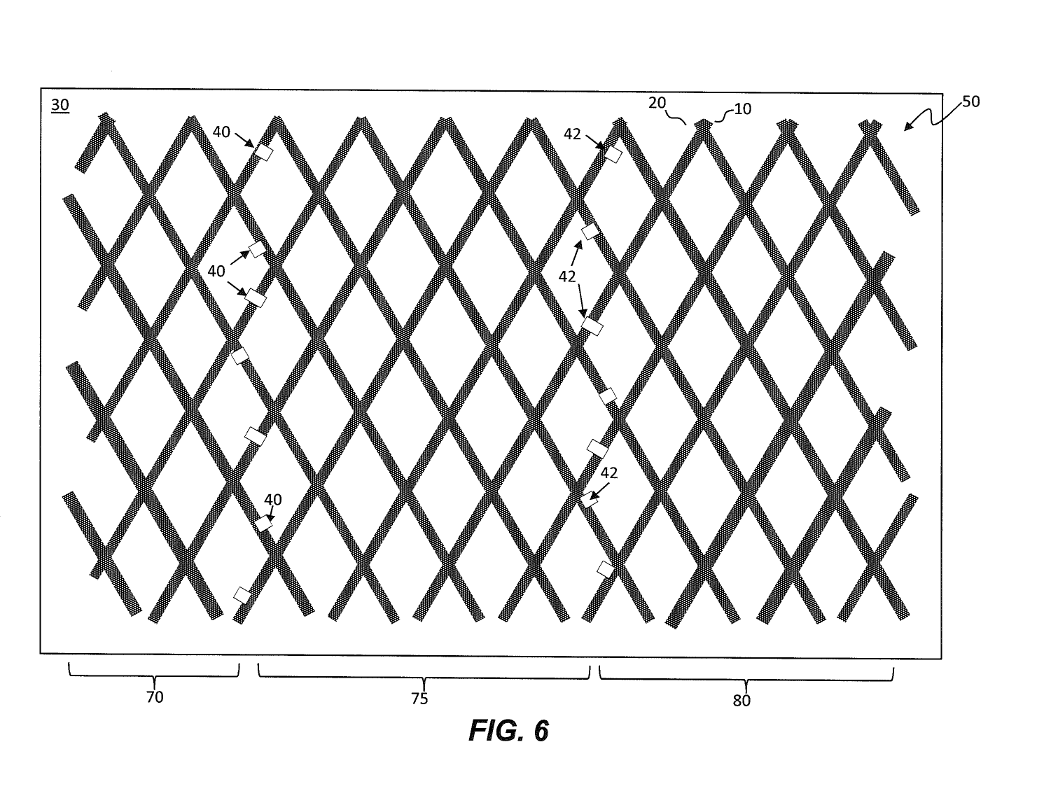

Referring to FIG. 6 in yet another embodiment, intersecting micro-wires 50 formed on, in, or above substrate 30 include first and second micro-wires 10, 20. Micro-wire gaps 40 in first and second micro-wires 10, 20 electrically isolate first and third electrodes 70 and 75. Micro-wire gaps 42 in first and second micro-wires 10, 20 electrically isolate third and second electrodes 75 and 80. The arrangement of micro-wire gaps 40 between two adjacent first and third electrodes 70, 75 is distinct and different from the arrangement of micro-wire gaps 42 between two other adjacent third and second electrodes 75, 80.

In further embodiments of the present invention, first electrode 70 (or second electrode 80) extends in an electrode direction that is parallel to the first direction of first micro-wires 10 (as shown in FIGS. 1 and 4) or parallel to the second direction of second micro-wires 20 (not shown). Alternatively, referring to FIGS. 2 and 5, first electrode 70 (or second electrode 80) extends in an electrode direction that is not parallel to the first direction of first micro-wires 10 or not parallel to the second direction of second micro-wires 20.

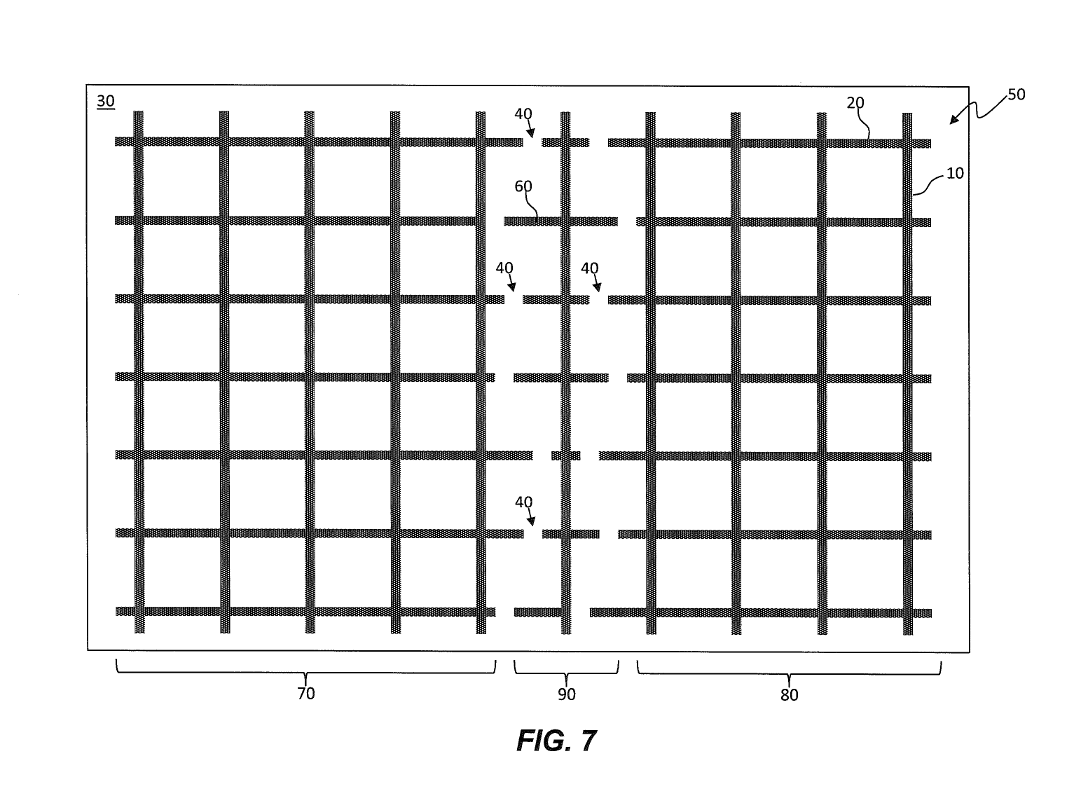

Referring to FIG. 7, intersecting micro-wires 50 formed on, in, or above substrate 30 include first and second micro-wires 10, 20. Dummy micro-wires 60 (that can include portions of one or more of first micro-wires 10 or second micro-wires 20) form dummy electrode 90 located between adjacent first and second electrodes 70, 80. Micro-wire gaps 40 in first or second micro-wires 10, 20 electrically isolate first and second electrodes 70, 80 from dummy electrode 90. Micro-wire gaps 40 are located in a non-linear arrangement. Dummy electrode 90 includes at least a portion of one first micro-wire 10 and at least a portion of one second micro-wire 20 that intersects with the portion of at least one first micro-wire 10.

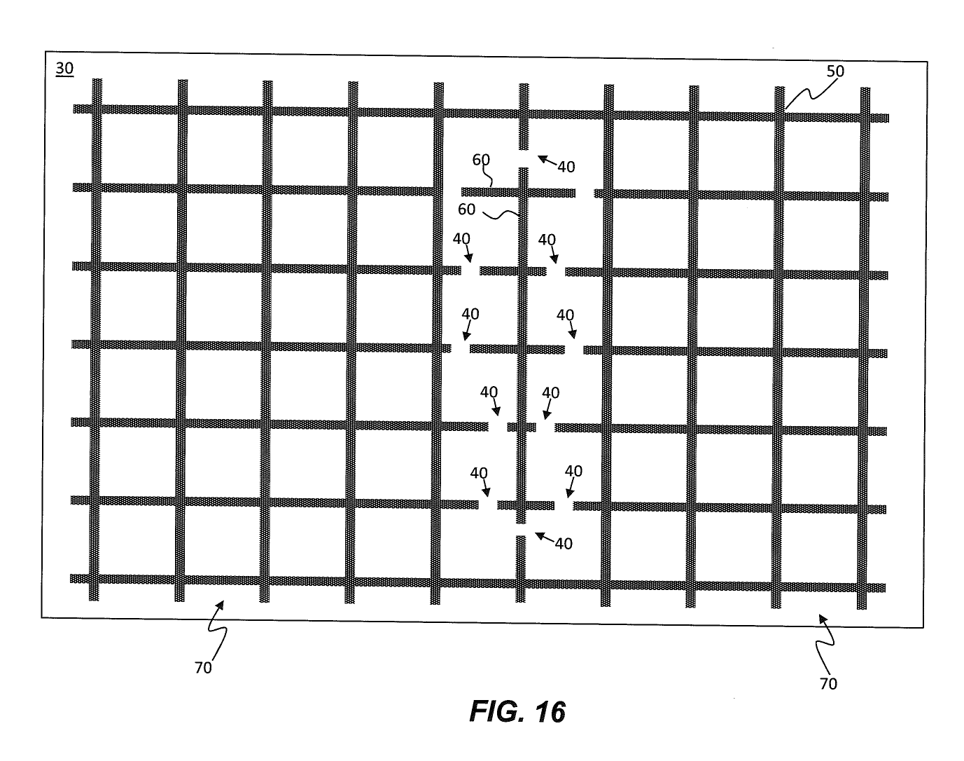

Referring to FIG. 16, micro-wire first electrode 70 formed on substrate 30 having micro-wires 50 surround dummy micro-wires 60. Dummy micro-wires 60 are separated and electrically isolated from micro-wires 50 of first electrode 70 by micro-wire gaps 40 located in a non-linear arrangement. Such an arrangement enables the isolation of portions of a micro-wire array from first electrodes 70.

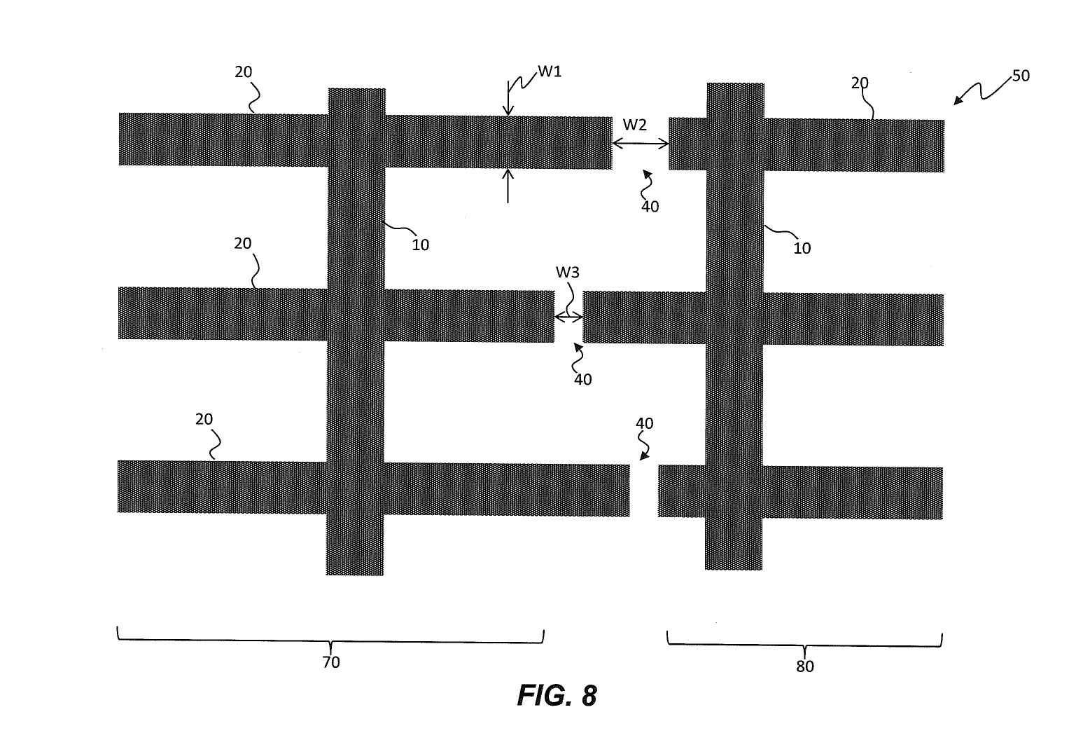

Referring to the embodiment illustrated in FIG. 8, micro-wires 50 include first and second micro-wires 10, 20. The length of a micro-wire gap width W2 in second micro-wire 20 is less than or equal to a micro-wire width W1 of first or second micro-wire 10, 20. Alternatively, at least one of micro-wire gaps 40 has a micro-wire gap width W2 different from a micro-wire gap width W3 of another one of micro-wire gaps 40. Such arrangements can reduce the visibility of micro-wire gaps 40.

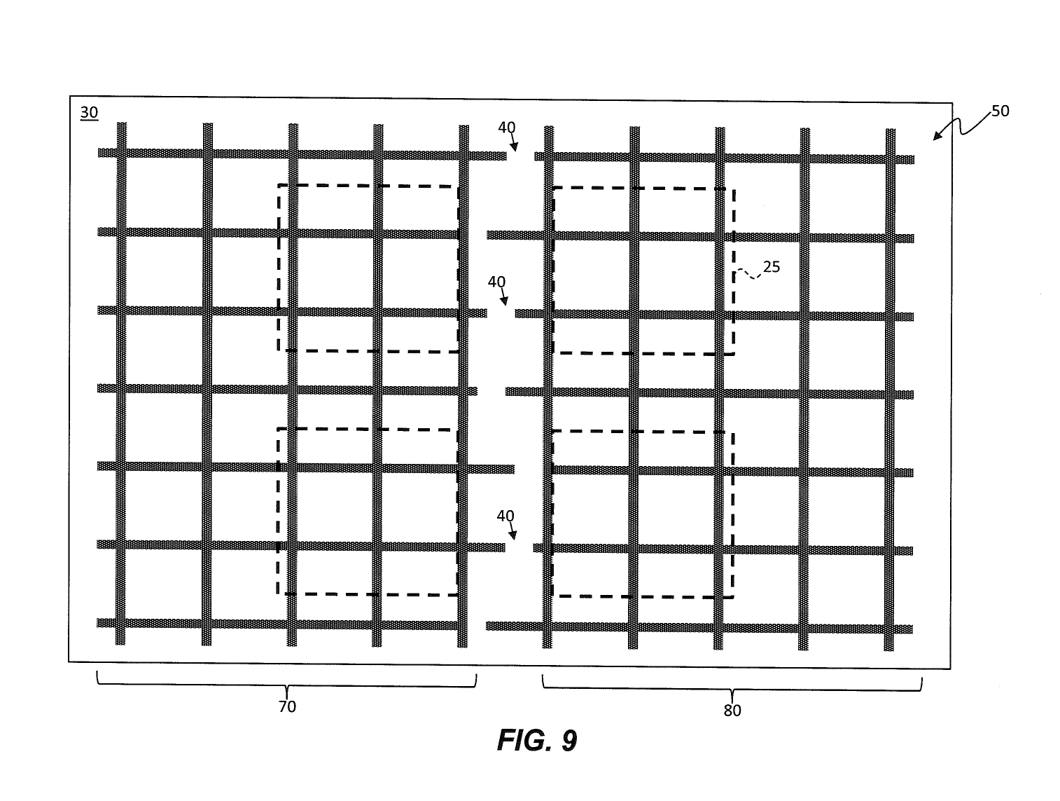

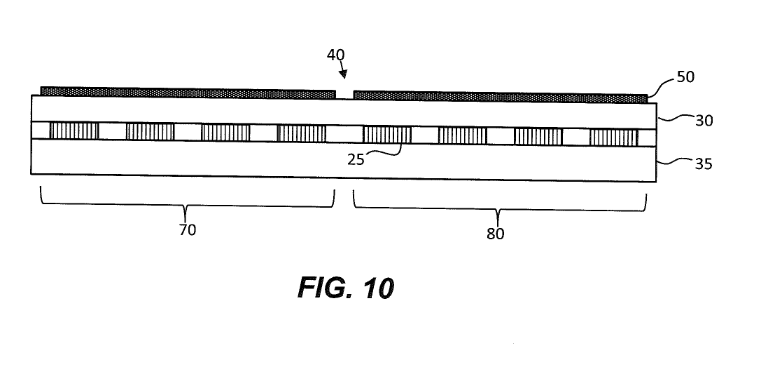

In yet another embodiment referring to the plan view of FIG. 9 and the cross section of FIG. 10, a micro-wire electrode structure further includes an array of spatially separated pixels or sub-pixels 25 arranged on a display substrate 35 above or below substrate 30. At least some, or in an embodiment all, of micro-wire gaps 40 formed in micro-wires 50 separating first and second electrodes 70, 80 are located between the pixels or sub-pixels 25. As intended herein, pixels 25 are picture elements used to form images in a display. Color pixels 25 typically include multiple sub-pixels 25, one for each color primary of the display. Pixels and sub-pixels are not distinguished herein. According to an embodiment, one or more micro-wire gaps 40 are located between the pixels or sub-pixels 25 when viewed by a user from a location at which the display is intended for viewing.

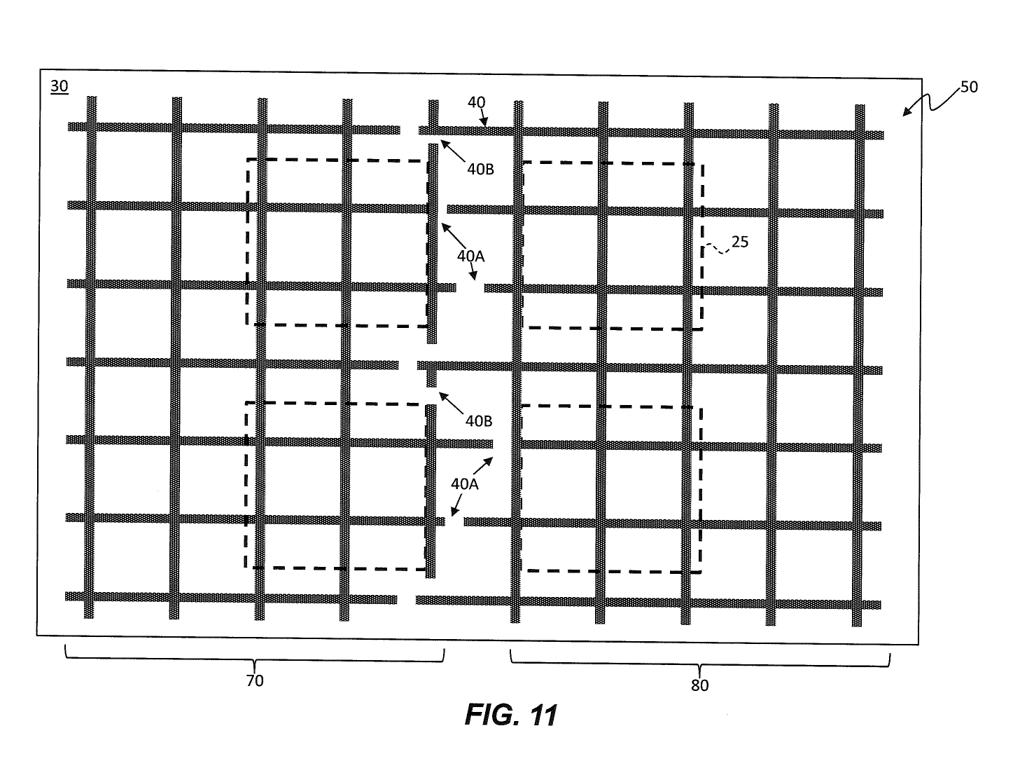

In an embodiment illustrated in FIG. 11, pixels or sub-pixels 25 are arranged in a two-dimensional array of rows and columns and at least one first micro-wire gap 40A is located between pixels or sub-pixels 25 in a column and at least one second micro-wire gap is 40B located between pixels or sub-pixels 25 in a row.

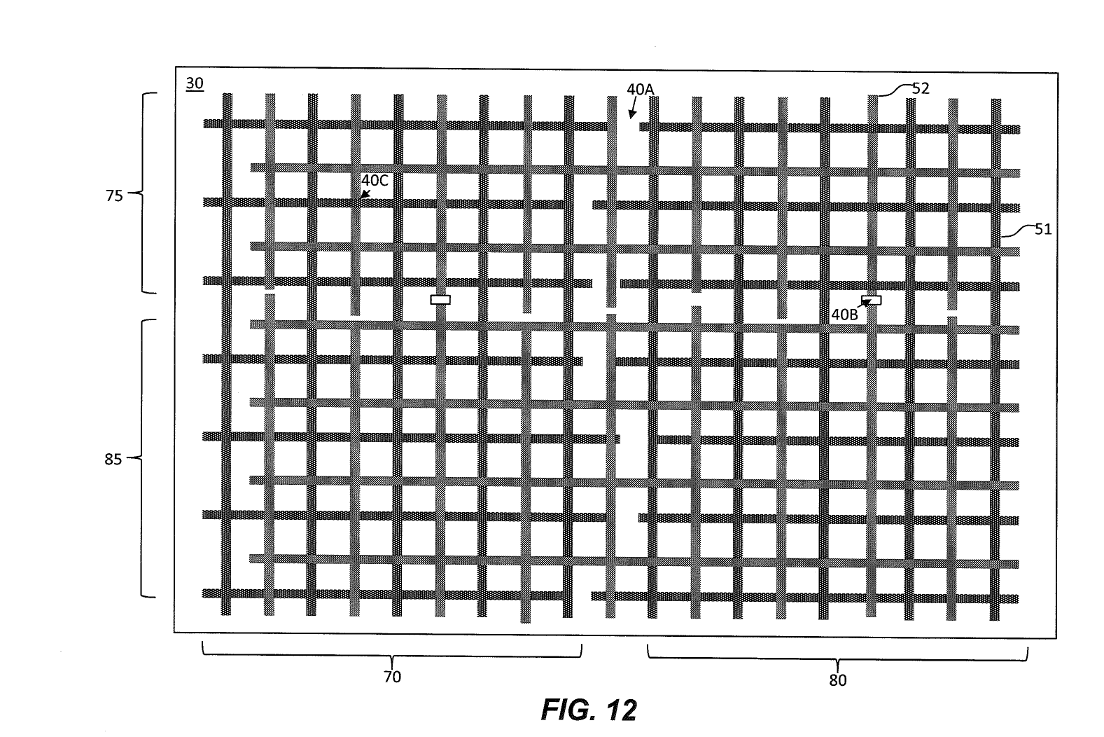

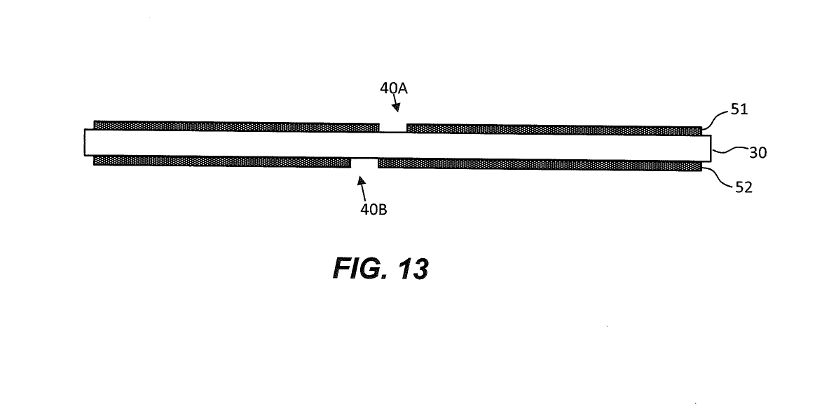

Referring to the plan view of FIG. 12 and the cross section of FIG. 13, a first plurality of first micro-wires 51 are formed on, in, or over, substrate 30 and a second plurality of second micro-wires 52 are formed below the first plurality of first micro-wires 51, for example on, in, or below substrate 30. Substrate 30 can be a dielectric layer. An array of first micro-wires 51 form first and second electrically isolated first and second electrodes 70, 80 separated by first micro-wire gaps 40A. An array of second micro-wires 52 form third and fourth electrically isolated electrodes 75, 85 separated by second micro-wire gaps 40B. (First, second, third, and fourth electrodes 70, 80, 75, 85 are not shown in FIG. 13.). First micro-wire gaps 40A are located in a non-linear arrangement. Second micro-wire gaps 40B are located in a non-linear arrangement. None of the second micro-wire gaps 40B is in a linear arrangement with two or more adjacent first micro-wire gaps 40A when projected onto a planar surface. Adjacent first micro-wire gaps 40A are the two first micro-wire gaps 40A closest to second micro-wire gap 40B when projected onto a planar surface.

In another embodiment, second micro-wire gaps 40C in second micro-wires 52 are located directly above micro-wires 51. In a further embodiment, the length of second micro-wire gap 40C in second micro-wire 52 is substantially equal to the width of first micro-wire 51. Alternatively, first micro-wire gaps 40A in first micro-wires 51 are located directly beneath micro-wires 52. In a further embodiment, the length of first micro-wire gap 40C in first micro-wire 51 is substantially equal to the width of second micro-wire 52.

Embodiments of the present invention provide reduced visibility of micro-wire electrode structures and micro-wire gaps 40 in micro-wires 50. Prior-art electrode structures using transparent conductive oxides differ from micro-wires 50 of the present invention in that micro-wires 50 are typically opaque. Hence, the problem addressed by the present invention does not arise for electrodes using transparent conductive oxides. Because micro-wire first and second electrodes 70, 80 use opaque micro-wires 50, conventionally located micro-wire gaps 40 as taught in the prior art can form an apparently lighter line visible to the human visual system. Since the human visual system is especially sensitive to straight lines, the present invention reduces the visibility of micro-wire gaps 40 separating first and second electrodes 70, 80 by locating micro-wire gaps 40 in a non-linear arrangement.

Micro-wires 50 can be formed directly on substrate 30 or over substrate 30 or on layers formed on substrate 30. The words “on”, “over’, or the phrase “on or over” indicate that micro-wires 50 can be formed directly on substrate 30, on layers formed on substrate 30, or on other layers or another substrate 30 located so that micro-wires 50 are over substrate 30. Likewise, micro-wires 50 can be formed on, under, or below substrate 30. The words “on”, “under”, “below” or the phrase “on or under” indicate that micro-wires 50 are formed directly on substrate 30, on layers formed on substrate 30, or on other layers or another substrate 30 located so that micro-wires 50 are under substrate 30. “Over” or “under”, as used in the present disclosure, are simply relative terms for layers located on or adjacent to opposing surfaces of a substrate (e.g. 30). By flipping substrate 30 and related structures over, layers that are over substrate 30 become under substrate 30 and layers that are under substrate 30 become over substrate 30.

Micro-wires 50 of the present invention can be used in touch-screens or other devices requiring first and second electrodes 70, 80 formed from micro-wires 50. Wires, buss connections, touch-screen controllers, or display controllers can be used to control and operate micro-wire first and second electrodes 70, 80 of the present invention.

In a useful embodiment of the present invention, substrate 30 is a cover or substrate of a display through which light is emitted or reflected by the display. In another embodiment, substrate 30 and micro-wires 50 are located in combination with, or as a part of, a display to form a touch-responsive capacitive device including a touch screen and display. Display devices having covers or substrates, for example OLED displays and liquid crystal displays are well known and can be used with the present invention.

Substrate 30 of the present invention can include any material capable of providing a supporting surface on which micro-wires 50 are formed and patterned. Substrates such as glass, metal, or plastics can be used and are known in the art together with methods for providing suitable surfaces. In a useful embodiment, substrate 30 is substantially transparent, for example having a transparency of greater than 90%, 80% 70% or 50% in the visible range of electromagnetic radiation.

Micro-wires 50 can be metal, for example silver, gold, aluminum, nickel, tungsten, titanium, tin, or copper or various metal alloys including, for example silver, gold, aluminum, nickel, tungsten, titanium, tin, or copper. Alternatively, micro-wires 50 can include cured or sintered metal particles such as nickel, tungsten, silver, gold, titanium, or tin or alloys such as nickel, tungsten, silver, gold, titanium, or tin. Conductive inks can be used to form micro-wires 50 with pattern-wise deposition and curing steps. Other materials or methods for forming micro-wires 50 can be employed and are included in the present invention. Other conductive metals or materials can be used. Micro-wires 50 can be, but need not be, opaque.

There are a variety of methods employable to make a micro-wire structure of the present invention. In one embodiment, substrate 30 is provided and coated with a curable layer. The curable layer can be a dielectric. The curable layer is embossed with a patterned stamp to form micro-channels in an arrangement of the present invention. The curable layer is cured and the micro-channels filled with conductive ink. The conductive ink is cured to form micro-wires 50 in a micro-wire electrode structure. Curing is accomplished, for example, by drying, heating, or irradiating with electromagnetic radiation.

Micro-wires 50 can be formed by patterned deposition of conductive materials or of patterned precursor materials that are subsequently processed, if necessary, to form a conductive material. Suitable methods and materials are known in the art, for example inkjet deposition or screen printing with conductive inks. Alternatively, micro-wires 50 can be formed by providing a blanket deposition of a conductive or precursor material and patterning and curing, if necessary, the deposited material to form a micro-pattern of micro-wires 50. Photo-lithographic and photographic methods are known to perform such processing. The present invention is not limited by the micro-wire materials or by methods of forming a pattern of micro-wires on a supporting substrate surface.

In any of these cases, precursor material is conductive after it is cured and any needed processing completed. Before patterning or before curing, the precursor material is not necessarily electrically conductive. As used herein, precursor material is material that is electrically conductive after any final processing is completed and the precursor material is not necessarily conductive at any other point in the micro-wire formation process.

In an example and non-limiting embodiment of the present invention, each micro-wire 50 is 5 microns wide and separated from neighboring micro-wires 50 by a distance of 50 microns or more, 100 microns or more, or 500 microns or more, so that the first and second electrode 70, 80 is apparently transparent. As used herein, apparently transparent refers to elements that transmit at least 50% of incident visible light, preferably 80% or at least 90%.

Methods and device for forming and providing substrates, coating substrates, patterning coated substrates, or pattern-wise depositing materials on a substrate are known in the photo-lithographic arts. Likewise, tools for laying out electrodes, conductive traces, and connectors are known in the electronics industry as are methods for manufacturing such electronic system elements. Hardware controllers for controlling electrodes, for example in touch screens, and displays and software for managing display and touch screen systems are well known. These tools and methods can be usefully employed to design, implement, construct, and operate the present invention. Methods, tools, and devices for operating capacitive touch screens can be used with the present invention.

Although the present invention has been described with emphasis on capacitive touch screen embodiments, the apparently transparent micro-wire electrodes of the present invention are useful in a wide variety of electronic devices. Such devices can include, for example, photovoltaic devices, OLED displays and lighting, LCD displays, plasma displays, inorganic LED displays and lighting, electrophoretic displays, electrowetting displays, dimming mirrors, smart windows, transparent radio antennae, transparent heaters and other touch screen devices such as resistive touch screen devices.

The invention has been described in detail with particular reference to certain embodiments thereof, but it will be understood that variations and modifications can be effected within the spirit and scope of the invention.

### PARTS LIST

W1 micro-wire width
W2 micro-wire gap width
W3 micro-wire gap width
10 first micro-wire
11 first micro-wire
12 first micro-wire
13 first micro-wire
20 second micro-wire
25 pixels/sub-pixels
30 substrate
35 display substrate
40 micro-wire gap
40A first micro-wire gap
40B second micro-wire gap
40C micro-wire gap
40D micro-wire gap
42 micro-wire gap
50 micro-wires
51 first micro-wires
52 second micro-wires
55 intersecting location
60 dummy micro-wire
70 first electrode
75 third electrode
80 second electrode
85 fourth electrode
90 dummy electrode

1. A micro-wire electrode structure having non-linear gaps, comprising:
a substrate;
a plurality of intersecting micro-wires formed over, on, or in the substrate, the plurality of intersecting micro-wires including first micro-wires extending in a first direction and second micro-wires extending in a second direction different from the first direction, the second micro-wires intersecting the first micro-wires;
wherein the plurality of intersecting micro-wires forms an array of electrically isolated electrodes, each electrode including both first and second micro-wires; and
wherein each electrode is separated from an adjacent electrode in the array of electrodes by micro-wire gaps in at least some of the micro-wires, the micro-wire gaps located in a non-linear arrangement.

2. The micro-wire electrode structure of claim 1, wherein the first or second micro-wires are straight.

3. The micro-wire electrode structure of claim 1, wherein the first or second micro-wires are curved or have curved portions.

4. The micro-wire electrode structure of claim 1, wherein the micro-wire gaps are formed in only the first micro-wires or the micro-wire gaps are formed only in the second micro-wires.

5. The micro-wire electrode structure of claim 1, wherein the micro-wire gaps are formed in both the first micro-wires and the second micro-wires or wherein the plurality of intersecting micro-wires form intersections at intersecting locations and at least one micro-wire gap is formed in an intersecting location.

6. The micro-wire electrode structure of claim 1, further including dummy micro-wires surrounded by electrode micro-wires and separated from the electrode micro-wires by micro-wire gaps located in a non-linear arrangement.

7. The micro-wire electrode structure of claim 1, wherein an electrode extends in an electrode direction that is parallel to the first direction or parallel to the second direction or wherein an electrode extends in an electrode direction that is not parallel to the first direction and is not parallel to the second direction.

8. The micro-wire electrode structure of claim 1, wherein the micro-wire gaps include a first micro-wire gap formed in a second micro-wire between two first micro-wires and a second micro-wire gap formed in a different second micro-wire, the first micro-wire gap and the second micro-wire gap formed between the same two first micro-wires.

9. The micro-wire electrode structure of claim 1, wherein the micro-wire gaps include a first micro-wire gap formed in a second micro-wire between two first micro-wires and a second micro-wire gap formed in a different second micro-wire, the first micro-wire gap and the second micro-wire gap formed between two different first micro-wires.

10. The micro-wire electrode structure of claim 9, wherein the two first micro-wires and the two different first micro-wires have one first micro-wire in common.

11. The micro-wire electrode structure of claim 1, further including a dummy electrode located between two adjacent electrodes, the dummy electrode separated from each of the two adjacent electrodes by micro-wire gaps in the first or second micro-wires, the micro-wire gaps located in a non-linear arrangement.

12. The micro-wire electrode structure of claim 11, wherein the dummy electrode includes at least one first micro-wire and at least one second micro-wire that intersects with the at least one first micro-wire.

13. The micro-wire electrode structure of claim 1, wherein the length of the micro-wire gap is less than or equal to the width of a first or second micro-wire or wherein at least one of the micro-wire gaps has a length different from another one of the micro-wire gaps.

14. The micro-wire electrode structure of claim 1, wherein the micro-wire gaps have an irregular or random arrangement.

15. The micro-wire electrode structure of claim 1, further including an array of spatially separated pixels or sub-pixels arranged on a display substrate above or below the substrate, and wherein at least some of the micro-wire gaps are located between the pixels or sub-pixels.

16. The micro-wire electrode structure of claim 15, wherein the pixels or sub-pixels are arranged in a two-dimensional array of rows and columns and where at least one micro-wire gap is located between pixels or sub-pixels in a row and at least one micro-wire gap is located between pixels or sub-pixels in a column.

17. The micro-wire electrode structure of claim 1, wherein the arrangement of micro-wire gaps between two adjacent electrodes is distinct and different from the arrangement of micro-wire gaps between two other adjacent electrodes.

18. A micro-wire electrode structure having non-linear gaps, comprising;
a substrate;
a first plurality of intersecting first micro-wires formed over, on, or in the substrate, the first plurality of intersecting first micro-wires forming an array of electrically isolated first electrodes, each first electrode separated from an adjacent first electrode in the array of electrodes by first micro-wire gaps in at least some of the first micro-wires, the first micro-wire gaps located in a non-linear arrangement;
a second plurality of intersecting second micro-wires formed below the first plurality of intersecting first micro-wires, the second plurality of intersecting second first micro-wires forming an array of electrically isolated second electrodes each second electrode separated from an adjacent second electrode in the array of electrodes by second micro-wire gaps in at least some of the second micro-wires, the second micro-wire gaps located in a non-linear arrangement; and
wherein none of the second micro-wire gaps is in a linear arrangement with two or more adjacent first micro-wire gaps when projected onto a planar surface.

19. The micro-wire electrode structure of claim 18, wherein at least some of the first micro-wire gaps are located directly above the second micro-wires or wherein at least some of the second micro-wire gaps are located directly beneath the first micro-wires.

20. A micro-wire electrode structure having non-linear gaps, comprising:
a substrate;
a plurality of intersecting micro-wires formed over, on, or in the substrate;
wherein the plurality of intersecting micro-wires forms an array of electrically isolated electrodes; and
wherein each electrode is separated from an adjacent electrode in the array of electrodes by micro-wire gaps in at least some of the micro-wires, the gaps located in a non-linear arrangement.
